(19) United States
(12) Patent Application Publication
(10) Pub. No.: US 2025/0347746 A1
(43) Pub. Date: Nov. 13, 2025

(54) ESTIMATION METHOD, ESTIMATION PROGRAM, ESTIMATION APPARATUS, AND ENERGY STORAGE APPARATUS

(71) Applicant: GS Yuasa International Ltd., Kyoto-shi (JP)

(72) Inventors: Satoshi KUNITA, Kyoto-shi (JP); Atsushi FUKUSHIMA, Kyoto-shi (JP)

(21) Appl. No.: 19/273,612

(22) Filed: Jul. 18, 2025

Related U.S. Application Data
(63) Continuation of application No. PCT/JP2023/045396, filed on Dec. 19, 2023.

(30) Foreign Application Priority Data
Jan. 19, 2023 (JP) 2023-006810

(51) Int. Cl. G01R 31/367; B60L 58/10; G01R 31/374; G01R 31/385; G01R 31/389; H01M 10/48

(52) U.S. Cl. CPC G01R 31/367; B60L 58/10; G01R 31/374; G01R 31/385; G01R 31/389; H01M 10/486

(57) ABSTRACT

An estimation method includes using an energy storage device model simulating a behavior of an energy storage device to estimate an estimated voltage value of the energy storage device when energization is performed in an assumed energization pattern, and correcting the estimated voltage value estimated by a correction value obtained based on an error in an estimated state value of the energy storage device.

### CROSS REFERENCE TO RELATED APPLICATIONS

This application claims the benefit of priority to Japanese Patent Application No. 2023-006810 filed on Jan. 19, 2023 and is a Continuation application of PCT Application No. PCT/JP2023/045396 filed on Dec. 19, 2023. The entire contents of each application are hereby incorporated herein by reference.

### BACKGROUND OF THE INVENTION

### 1. Field of the Invention

The present invention relates to estimation methods, non-transitory computer-readable media including estimation programs, estimation apparatuses, and energy storage apparatuses.

### 2. Description of the Related Art

In order to achieve an automatic driving function and a safety function in a mobile object, there is a need to estimate power supply performance of an energy storage device mounted on a vehicle or the like.

A battery control apparatus disclosed in Japanese Unexamined Patent Application Publication No. 2015-114135 simulates a charge/discharge behavior of a storage battery by regarding the storage battery as an electrical equivalent circuit, thereby calculating chargeable/dischargeable power of the storage battery.

### SUMMARY OF THE INVENTION

In estimation of the power supply performance of an energy storage device using an energy storage device model such as an equivalent circuit, a state value indicating a state of the energy storage device is necessary. The state value is often a value that cannot be directly measured, and an estimated state value obtained by estimating the state of the energy storage device is usually used as the state value. Regarding the estimation of the power supply performance using such an estimated state value, consideration of an error in the estimated state value has not been sufficiently studied yet. When the error in the estimated state value increases, the estimation error in the power supply performance also increases, and estimation accuracy of the power supply performance deteriorates.

Example embodiments of the present invention provide techniques to accurately estimate power supply performance of energy storage devices.

An estimation method according to an example embodiment of the present disclosure includes using an energy storage device model simulating a behavior of an energy storage device to estimate an estimated voltage value of the energy storage device when energization is performed in an assumed energization pattern, and correcting the estimated voltage value that has been estimated by a correction value obtained based on an error in an estimated state value of the energy storage device.

According to example embodiments of the present disclosure, it is possible to accurately estimate the power supply performance of the energy storage device.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view illustrating a configuration example of an energy storage apparatus.

FIG. 2 is an exploded perspective view of an energy storage apparatus.

FIG. 3 is a block diagram illustrating a configuration example of an energy storage apparatus including an estimation apparatus.

FIG. 4 is a diagram illustrating an example of an assumed energization pattern.

FIG. 5 is a diagram explaining a method of estimating whether or not energization in an assumed energization pattern is possible.

FIG. 6 is a circuit diagram illustrating an example of an energy storage device model.

FIG. 7 is a conceptual diagram illustrating an example of a data table of circuit parameters.

FIG. 8 is a diagram explaining a method of estimating an SOC error.

FIG. 9 is a diagram explaining a method of estimating a temperature error caused by energization.

FIG. 10 is a diagram illustrating a method of estimating a temperature error caused by a change in ambient temperature.

FIG. 11 is a flowchart illustrating an example of a processing procedure to be executed by the estimation apparatus.

FIG. 12 is a flowchart illustrating an example of a processing procedure to be executed by the estimation apparatus.

### DETAILED DESCRIPTION OF THE EXAMPLE EMBODIMENTS

(1) An estimation method according to an example embodiment of the present disclosure includes using an energy storage device model simulating a behavior of an energy storage device to estimate an estimated voltage value of the energy storage device when energization is performed in an assumed energization pattern, and correcting the estimated voltage value that has been estimated by a correction value obtained based on an error in an estimated state value of the energy storage device.

Here, the “energy storage device” may be an energy storage cell, or may be an energy storage assembly (energy storage apparatus) including a plurality of energy storage cells.

The assumed energization pattern may be, for example, a current pattern based on an energization time and an operating voltage range of the energy storage device.

According to the estimation method described in the above (1), since the estimated voltage value is corrected with the correction value efficiently and appropriately obtained based on the error in the estimated state value, it is possible to accurately estimate power supply performance (SOF: State Of Function) of the energy storage device.

The estimated voltage value (unit: volt (V)) of the energy storage device when energization is performed in the assumed energization pattern is obtained by using the estimated state value of the energy storage device and the energy storage device model. The estimated state value is a value that cannot be directly measured, and includes, for example, values such as a state of charge (SOC), an internal resistance, and an internal temperature of the energy storage device. The estimated state value may deviate from the actual state value of the energy storage device (an error may occur). By setting an error that may occur between the estimated state value and the actual state value (a difference between the estimated state value and the actual state value) in advance in association with an input element to the energy storage device model, such as a measured value, for example, a measured temperature value, it is possible to efficiently and accurately obtain the correction value (V) of the estimated state value, based on the set error. By correcting the estimated voltage value with the acquired correction value (V), charge acceptance performance or discharge performance of the energy storage device can be appropriately estimated without being overestimated or underestimated.

The behavior (estimated voltage value) of the energy storage device, which is output by the energy storage device model, is also an example of the estimated state value of the energy storage device. By setting the error caused by the energy storage device model in advance depending on, for example, a length of the energization time of the assumed energization pattern to be applied to the energy storage device model, it is possible to efficiently and accurately obtain the correction value of the estimated state value, based on the set error.

In particular, when the energy storage device is used for a mobile object such as a vehicle, it is required to estimate the SOF with high accuracy and with a short delay time in order to reliably operate an automatic driving function and a safety function of the vehicle. According to the above-described configuration, the reliability of SOF estimation can be improved.

(2) The estimation method described in the above (1) may further include acquiring a measured current value, a measured voltage value, and a measured temperature value of the energy storage device, and the estimated voltage value may be estimated by using the acquired measured current value, the measured voltage value, and the measured temperature value, and the energy storage device model.

(3) In the estimation method described in the above (1) or (2), the correction value may be obtained to be smaller than a sum of individual correction values obtained from respective maximum errors of a plurality of estimated state values of the energy storage device.

Here, the maximum error in the estimated state value may be a maximum value of an error assumed when the error is obtained by a predetermined estimation method.

When there are a plurality of types of estimated state values that affect voltage characteristics of the energy storage device, it is necessary to obtain the correction value in consideration of errors of the plurality of estimated state values. The present inventors have focused on the fact that errors of the plurality of estimated state values occur independently of each other, and have found that when the sum of individual correction values obtained from the respective maximum errors of the plurality of estimated state values is used as the correction value, the correction value is larger than necessary. According to the estimation method described in the above (3), by obtaining the correction value so as to be smaller than the sum of the individual correction values obtained from the respective maximum errors of the plurality of estimated state values, it is possible to prevent the charge acceptance performance or discharge performance of the energy storage device from being underestimated (i.e., to prevent the energy storage device from being unable to sufficiently exert its performance).

(4) In the estimation method described in any one of the above (1) to (3), the error in the estimated state value may increase as an elapsed time from a predetermined timing increases.

The predetermined timing may be, for example, a timing at which a previous or most recent state value is accurately estimated, a timing at which an error in the previous or most recent estimated state value is reset, or the like.

According to the estimation method described in the above (4), a length of the elapsed time, which is a cause of an occurrence of an error in the estimated state value, can be reflected in the error in the estimated state value. It is possible to suitably correct an error in the estimated state value whose deviation from an actual state value becomes large according to the length of the elapsed time.

(5) In the estimation method described in any one of the above (1) to (4), the error in an internal temperature of the energy storage device, among the estimated state values, may be increased depending on a magnitude of a change in an ambient temperature or a magnitude of an energization amount of the energy storage device.

According to the estimation method described in the above (5), the ambient temperature or the energization amount of the energy storage device, which is a cause of an occurrence of an error in the internal temperature among the estimated state values, can be reflected in the error in the estimated state value. It is possible to suitably correct an error in the internal temperature whose deviation from an actual state value becomes large according to the magnitude of the change in the ambient temperature or the magnitude of the energization amount due to charge and discharge.

(6) In the estimation method described in any one of the above (1) to (5), the error in an output of the energy storage device model among the estimated state values may be increased depending on at least one of a length of an energization time of the assumed energization pattern, a magnitude of a current, a magnitude of current fluctuation, or a number of times of current fluctuation.

According to the estimation method described in the above (6), at least one of the length of the energization time of the assumed energization pattern, the magnitude of the current, the magnitude of the current fluctuation, or the number of times of the current fluctuation, which are causes of an occurrence of an error in the output of the energy storage device model among the estimated state values, can be reflected in the error in the estimated state value. It is possible to suitably correct an error in an output of an energy storage device model, whose deviation from an actual state value becomes large according to the length of the energization time, the magnitude of the current, the magnitude of the current fluctuation, or the number of times of the current fluctuation.

(7) In the estimation method described in any one of the above (1) to (6), the energy storage device is an energy storage assembly including a plurality of energy storage cells, a measured voltage value and a measured temperature value of each of the plurality of energy storage cells are acquired, and an estimated voltage value of the energy storage assembly may be obtained from an estimated voltage value of each of the plurality of energy storage cells, which is estimated by using the acquired measured voltage value and measured temperature value of each of the plurality of energy storage cells.

In the energy storage assembly including a plurality of energy storage cells, in many cases, the measured voltage value and the measured temperature value are different for each energy storage cell. According to the estimation method described in the above (7), by acquiring the measured voltage value and the measured temperature value of each of the plurality of energy storage cells, it is possible to appropriately obtain the estimated voltage value of each energy storage cell when energization is performed in the assumed energization pattern, and as a result, it is possible to appropriately obtain the estimated voltage value of the energy storage assembly.

(8) In the estimation method described in any one of the above (1) to (7), whether or not the energy storage device can be charged or discharged in the assumed energization pattern may be determined based on the estimated voltage value and the correction value.

According to the estimation method described in the above (8), it is possible to accurately determine whether or not the energy storage device can be charged or discharged, based on a voltage behavior of the energy storage device accurately estimated by correction. The determination result as to whether charge or discharge is possible may be output to a host apparatus (for example, an electronic control unit (ECU) of the vehicle, a monitoring apparatus installed remotely, a cloud server, or the like).

(9) A non-transitory computer-readable medium according to an example embodiment of the present disclosure includes an estimation program executable to cause a computer to perform using an energy storage device model simulating a behavior of an energy storage device to estimate an estimated voltage value of the energy storage device when energization is performed in an assumed energization pattern, and correcting the estimated voltage value that has been estimated by a correction value obtained based on an error in an estimated state value of the energy storage device.

(10) An estimation apparatus according to an example embodiment of the present disclosure includes a processor, a memory including a program executable by the processor to function as an estimation section configured or programmed to use an energy storage device model simulating a behavior of an energy storage device to estimate an estimated voltage value of the energy storage device when energization is performed in an assumed energization pattern, and a correction section configured or programmed to correct the estimated voltage value that has been estimated by a correction value obtained based on an error in an estimated state value of the energy storage device.

(11) An energy storage apparatus according to an example embodiment of the present disclosure includes the estimation apparatus according to the above (10).

According to the energy storage apparatus according to the above (11), it is possible to easily estimate the power supply performance in the energy storage apparatus. By locally performing processing in a short time without going through communication with an external apparatus, responsiveness can be improved. By edge computing in which power supply performance is estimated in an energy storage apparatus, a mobile object, a facility, or the like on which the energy storage apparatus is mounted can use the energy storage apparatus more safely and stably.

Hereinafter, the present disclosure will be specifically explained with reference to the drawings illustrating example embodiments thereof.

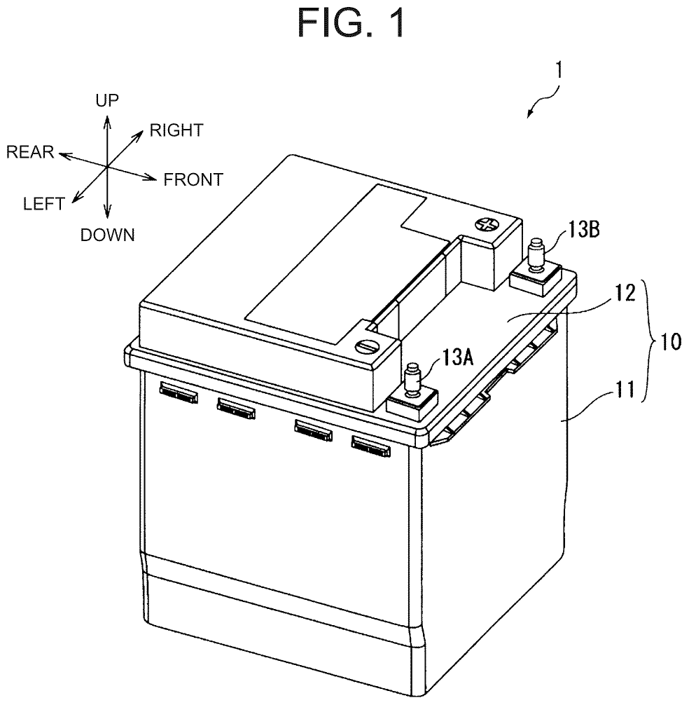

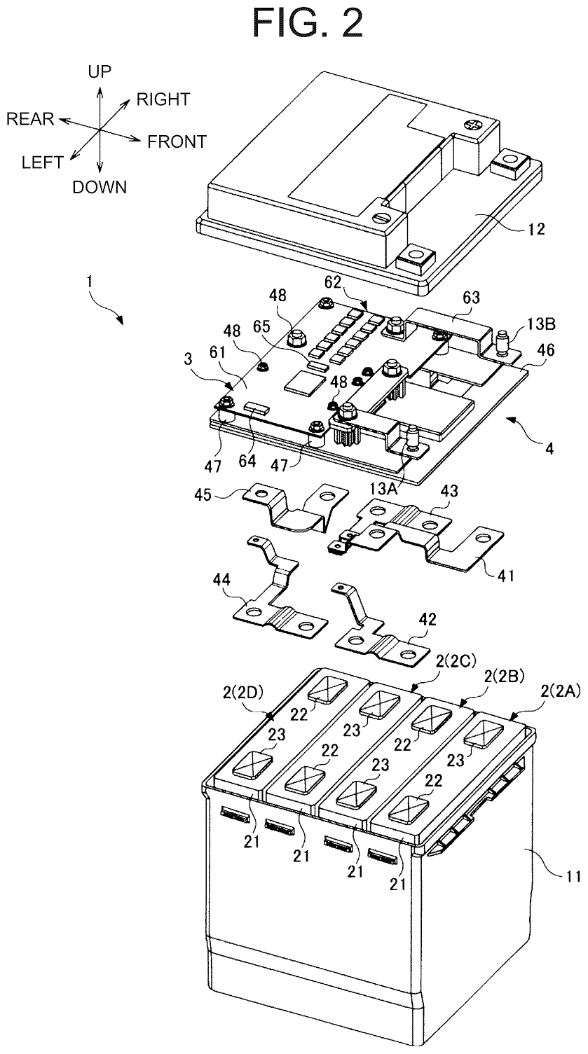

FIG. 1 is a perspective view illustrating a configuration example of an energy storage apparatus 1, and FIG. 2 is an exploded perspective view of the energy storage apparatus 1. Hereinafter, a configuration example of the energy storage apparatus 1 will be described with reference to each direction of “front-rear”, “left-right”, and “up-down” illustrated in the drawings.

The energy storage apparatus 1 is, for example, a battery which is suitably mounted on, for example, an engine vehicle, an electric vehicle (EV), a hybrid electric vehicle (HEV), a plug-in hybrid electric vehicle (PHEV), or the like. The energy storage apparatus 1 is, for example, a 12-volt (V) battery or a 48 V battery.

The energy storage apparatus 1 includes a plurality of energy storage cells 2, an estimation apparatus 3, and a bus bar unit 4. The energy storage apparatus 1 is an example of an energy storage device. The energy storage cells 2, the estimation apparatus 3, and the bus bar unit 4 are housed inside a housing case 10. The energy storage cell 2 is, for example, a battery cell utilizing a lithium-ion secondary battery.

In the present example embodiment, the energy storage device is an energy storage assembly including a plurality of energy storage cells 2. Alternatively, the energy storage device may be a single energy storage cell 2.

The estimation apparatus 3 is a flat plate-shaped circuit board. The estimation apparatus 3 is, for example, a battery management system (BMS). The estimation apparatus 3 acquires measurement data including voltages of the energy storage cell 2 and the energy storage apparatus 1, a current that flows through the energy storage cell 2, and a temperature related to the energy storage apparatus 1. The estimation apparatus 3 estimates power supply performance of the energy storage apparatus 1 by using an energy storage device model, based on the acquired measurement data.

In the present example embodiment, the estimation apparatus 3 is mounted inside the energy storage apparatus 1. Alternatively, the estimation apparatus 3 may be installed away from the energy storage apparatus 1. The estimation apparatus 3 may be a computer, such as a server apparatus, a terminal apparatus, or a vehicle ECU, which is connected to the outside of the energy storage apparatus 1. In this case, the measurement data measured regarding the energy storage apparatus 1 may be transmitted to a server apparatus or the like by communication.

The housing case 10 is made of synthetic resin. The housing case 10 includes: a case main-body 11 with an upper surface opened; and a cover 12 covering the opening of the case main-body 11. The case main-body 11 and the cover 12 are liquid-tightly fixed to each other by a fastener such as a screw, an adhesive, welding, or the like, in a state in which the energy storage cells 2, the estimation apparatus 3, and the bus bar unit 4 are housed therein. A pair of external terminals 13A and 13B having different polarities are provided on one side surface of the housing case 10.

The energy storage cell 2 includes a case 21 having a hollow rectangular parallelepiped shape. A positive terminal 22 and a negative terminal 23 of the energy storage cell 2 are provided on an upper surface of the case 21. An electrode body, an electrolyte solution, and the like, which are not illustrated, are housed inside the case 21.

The electrode body is configured by stacking a sheet-shaped positive electrode and a sheet-shaped negative electrode with two sheet-shaped separators interposed therebetween, and then winding (vertically winding or horizontally winding) these. The separator is formed of a porous resin film. As the porous resin film, a porous resin film made of a resin such as polyethylene (PE) or polypropylene (PP) can be used.

The positive electrode is an electrode plate in which a positive electrode active material layer is formed on a surface of a long band-shaped positive electrode substrate made of, for example, aluminum, an aluminum alloy, or the like. The positive electrode active material layer includes a positive electrode active material. A material capable of absorbing and releasing lithium ions can be used as the positive electrode active material used in the positive electrode active material layer. Examples of the positive electrode active material include LiFePO₄. The positive electrode active material layer may further include a conductive auxiliary agent, a binder, and the like.

The negative electrode is an electrode plate in which a negative electrode active material layer is formed on a surface of a long band-shaped negative electrode substrate made of, for example, copper or a copper alloy. The negative electrode active material layer includes a negative electrode active material. As the negative electrode active material, a material capable of absorbing and releasing lithium ions can be used. Examples of the negative electrode active material include graphite, hard carbon, and soft carbon. The negative electrode active material layer may further include a binder, a thickener, and the like.

As the electrolyte, an electrolyte similar to that of a conventional lithium-ion secondary battery can be used. For example, as the electrolyte, an electrolyte in which a supporting salt is contained in an organic solvent can be used. As the organic solvent, for example, an aprotic solvent such as carbonates, esters, or ethers is used. As the supporting salt, for example, a lithium salt such as LiPF₆, LiBF₄, or LiClO₄ is suitably used. The electrolyte may include, for example, various additives such as a gas generating agent, a coating film forming agent, a dispersing agent, and a thickener.

In the present example embodiment, the energy storage cell 2 is a battery cell utilizing a lithium-ion secondary battery. Alternatively, the energy storage cell 2 may be a battery cell such as an all-solid-state battery, a lead battery, a redox flow battery, a zinc-air battery, an alkaline manganese battery, a lithium-sulfur battery, a sodium-sulfur battery, a silver oxide-zinc battery, a nickel-hydrogen battery, or a molten salt thermal battery, or may be a capacitor.

In the present example embodiment, the energy storage cell 2 is a rectangular battery cell including a wound electrode body. Alternatively, the energy storage cell 2 may be a cylindrical battery cell or a laminated (pouch-shaped) battery cell, or may be a battery cell provided with a laminated electrode body.

In the present example embodiment, the number of energy storage cells 2 housed in the case main-body 11 is four. Alternatively, the number of the energy storage cells 2 housed in the case main-body 11 may be greater than or equal to one and less than four, or may be greater than four. In the following description, the energy storage cells 2 are also referred to as a first energy storage cell 2A, a second energy storage cell 2B, a third energy storage cell 2C, and a fourth energy storage cell 2D in this order from the front side of the case main-body 11.

As illustrated in FIG. 2, each energy storage cell 2 is housed in the case main-body 11 in such a way that orientations of the positive terminals 22 and the negative terminals 23 of the energy storage cells 2 adjacent to each other are reversed.

The bus bar unit 4 is disposed on a terminal surface of the energy storage cell 2. The bus bar unit 4 includes: a plurality of bus bars 41 to 45; and a bus bar frame 46 made of resin and holding these bus bars 41 to 45. The bus bar frame 46 covers the upper side of the plurality of energy storage cells 2 and blocks radiant heat emitted from the plurality of energy storage cells 2. The estimation apparatus 3 is disposed on an upper surface of the bus bar frame 46. The estimation apparatus 3 is fixed to the bus bar frame 46 via a spacer 47 in a state of being separated from the upper surface of the bus bar frame 46. Since a heat insulating layer such as the bus bar frame 46 or air exists between the estimation apparatus 3 and the energy storage cells 2, the estimation apparatus 3 is disposed to be thermally separated from the energy storage cells 2. In the present example embodiment, the metal members that directly couple the estimation apparatus 3 and the energy storage cells 2 are only the bus bars 41 to 45.

The bus bars 41 to 45 constitute a charge/discharge path for the energy storage cells 2. The bus bars 41 to 45 are made of metal, and are formed of a material having excellent electrical conductivity and high thermal conductivity, such as aluminum, an aluminum alloy, copper, a copper alloy, or stainless steel. The bus bar 41 connects the negative terminal 23 of the first energy storage cell 2A and one external terminal 13A. The bus bar 45 connects the positive terminal 22 of the fourth energy storage cell 2D and an other external terminal 13B. The bus bars 42 to 44 electrically connect, in the energy storage cells 2 adjacent to each other, the positive terminal 22 of one energy storage cell 2 and the negative terminal 23 of the other energy storage cell 2.

The bus bars 41 to 45 are coupled to a lower surface of the estimation apparatus 3 by fasteners 48 such as screws. The energy storage cells 2 and the estimation apparatus 3 are connected to each other via the bus bars 41 to 45. Heat on the estimation apparatus 3 is transferred to the energy storage cells 2 via the fasteners 48 and the bus bars 41 to 45. Heat generated in the energy storage cells 2 during charge and discharge is transferred to an upper surface of the estimation apparatus 3 via the bus bars 41 to 45 and the fasteners 48.

In FIGS. 1 and 2, a configuration in which the four energy storage cells 2 are connected in series by the bus bars 41 to 45 has been described. Alternatively, some or all of the energy storage cells 2 may be connected in parallel.

The estimation apparatus 3 includes a board 61 made of resin. A blocking circuit 62, a first temperature sensor 64, a second temperature sensor 65, and the like are mounted on an upper surface of the board 61.

The blocking circuit 62 is a circuit for connecting or blocking a conduction path between the bus bar 45 connected to a positive terminal 22 of a fourth energy storage device 2D and a bus bar 63 connected to the external terminal 13B. The blocking circuit 62 is constituted by, for example, a semiconductor switch such as a metal oxide semiconductor field effect transistor (MOSFET). In the example of FIG. 2, six conduction paths extending in the front-rear direction are formed as the conduction paths between the bus bars 45 and 63, and two MOSFETs are connected in series to each of the six conduction paths (and internal body diodes are connected in reverse directions). The two MOSFETs disposed in each conduction path have a function as a switch that connects or blocks the conduction path, and also have a function of preventing a current from flowing out from the energy storage cell 2 to the outside and a current from flowing into the energy storage cell 2 from the outside when the conduction path is blocked. Alternatively, the blocking circuit 62 may be constituted by a relay switch.

The first temperature sensor 64 is a temperature sensor, such as a thermistor or a thermocouple, in which a periphery of a sensor portion is insulated by a synthetic resin material or the like. The first temperature sensor 64 measures a temperature correlated with an internal temperature of the energy storage apparatus 1 (energy storage cell 2). In the present example embodiment, the first temperature sensor 64 measures an ambient temperature of the energy storage apparatus 1. The ambient temperature of the energy storage apparatus 1 represents a temperature of a space (air) inside the energy storage apparatus 1. The first temperature sensor 64 may be disposed at a position sufficiently separated from the blocking circuit 62 and the like in such a way as not to be affected by heat from an energized heating element.

As described above, it is difficult to directly measure the temperature inside the energy storage cell 2. In the present example embodiment, the temperature around the energy storage cell 2, which has been measured by the first temperature sensor 64, is used as a substitute for the internal temperature of the energy storage apparatus 1.

The second temperature sensor 65 is a temperature sensor such as a thermistor or a thermocouple, in which a periphery of a sensor portion is insulated by a synthetic resin material or the like. The second temperature sensor 65 measures a temperature of the energized heating element on the board 61. In the example of FIG. 2, the energized heating element is a semiconductor switch included in the blocking circuit 62. An amount of heat generated by the energized heating element changes according to the energization amount of the energy storage apparatus 1. For example, when the energy storage apparatus 1 is charged and discharged at a high rate, heat generation of the semiconductor switch becomes large. The second temperature sensor 65 is disposed in a vicinity of the energized heating element. The vicinity of the energized heating element represents a position where heat of the energized heating element is transferred and detected as a temperature change on the upper surface of the board 61. When a balancer that balances charge states (voltages) of the plurality of energy storage cells 2 is mounted on the board 61, the second temperature sensor 65 may be disposed in the vicinity of the balancer (an other example of the energized heating element).

In the present example embodiment, the first temperature sensor 64 is disposed at a position separated from the blocking circuit 62, and measures the ambient temperature of the energy storage apparatus 1. Alternatively, the first temperature sensor 64 may be disposed on a surface of the energy storage cell 2, in the vicinity of a bus bar connecting the energy storage cell 2 and the estimation apparatus 3, or in the vicinity of the fastener 48. In this case, the first temperature sensor 64 detects a temperature that more strongly reflects the influence of heat of the energy storage cell 2.

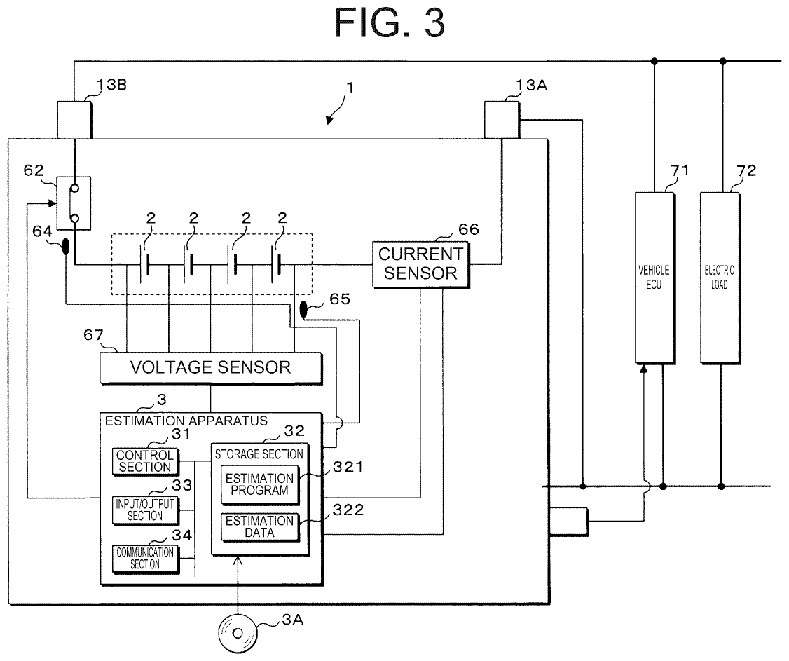

The case main-body 11 further houses therein a current sensor 66 and a voltage sensor 67 (refer to FIG. 3), which are not illustrated. The current sensor 66 is, for example, a shunt resistor, a current transformer, a Hall effect type current sensor, or the like, and measures the magnitude and direction (whether it is a charge direction or a discharge direction) of a current that flows through the energy storage cell 2. The voltage sensor 67 measures a terminal voltage of each energy storage cell 2.

FIG. 3 is a block diagram illustrating a configuration example of the energy storage apparatus 1 including the estimation apparatus 3. The energy storage apparatus 1 is connected to a vehicle electronic control unit (ECU) 71, a starter motor for starting an engine, and an electric load 72 such as an electric component, via the external terminals 13A and 13B. When the starter motor is rotated or when the vehicle is started, the energy storage apparatus 1 discharges to supply electric power to the electric load 72.

The vehicle ECU 71 is a vehicle control section that controls the vehicle. The vehicle ECU 71 controls the electric load 72. The vehicle ECU 71 controls a charging voltage and an allowable charge/discharge amount of the energy storage apparatus 1 by controlling the electric load 72, based on an estimation result related to the charge/discharge performance received from the estimation apparatus 3. The vehicle ECU 71 is an example of the “host apparatus”.

The estimation apparatus 3 includes a control section 31, a storage section 32, an input/output section 33, a communication section 34, and the like. In the present example embodiment, the estimation apparatus 3 is achieved by a circuit board, but alternatively, the estimation apparatus 3 may be configured by a plurality of computers for distributed processing, may be achieved by a plurality of virtual machines provided in one server, or may be achieved by using a cloud server.

The control section 31 is an arithmetic circuit including a central processing unit (CPU), a graphics processing unit (GPU), a read only memory (ROM), a random access memory (RAM), and the like. The CPU or GPU included in the control section 31 executes various computer programs stored in the ROM or the storage section 32, and controls operation of each of the above-described hardware units. The control section 31 may have functions of a timer that measures an elapsed time from when a measurement start instruction is given to when a measurement end instruction is given, a counter that counts the number, a clock that outputs date and time information, and the like.

The storage section 32 includes a non-volatile storage device such as a flash memory or a hard disk drive. The storage section 32 stores therein various computer programs, data, and the like to be referred to by the control section 31. The storage section 32 may be an external storage device connected to the estimation apparatus 3.

The storage section 32 according to the present example embodiment stores an estimation program 321 for causing a computer to execute processing related to the estimation of the power supply performance of the energy storage apparatus 1, and estimation data 322 as data necessary for execution of the estimation program 321. The estimation data 322 includes an energy storage device model used in simulation. The energy storage device model is described by configuration information indicating a circuit configuration, a value of each device constituting the energy storage device model, and the like. The storage section 32 stores therein configuration information indicating a circuit configuration of the energy storage device model, a value of each element constituting the energy storage device model, and the like.

A computer program (program product) including the estimation program 321 may be provided by a non-transitory recording medium 3A in which the computer program is recorded in a readable manner. The recording medium 3A is, for example, a portable memory such as a magnetic disk, an optical disk, or a semiconductor memory. The control section 31 reads a desired computer program from the recording medium 3A by using a reading device not illustrated, and stores the read computer program in the storage section 32. Alternatively, the above-described computer program may be provided by communication. The estimation program 321 may be configured by a single computer program or a plurality of computer programs, and may be executed on a single computer or a plurality of computers interconnected by a communication network.

The input/output section 33 includes an input/output interface for connecting an external apparatus. The input/output section 33 is connected to the blocking circuit 62, the first temperature sensor 64, the second temperature sensor 65, the current sensor 66, the voltage sensor 67, and the like. The control section 31 acquires, as needed, data of the temperatures measured by the first temperature sensor 64 and the second temperature sensor 65, data of the current measured by the current sensor 66, and data of the voltage measured by the voltage sensor 67, through the input/output section 33. Further, the control section 31 switches between an ON state and an OFF state of the blocking circuit 62 by outputting a control signal to the blocking circuit 62 through the input/output section 33.

A display device such as a liquid crystal display device may be connected to the input/output section 33. The control section 31 outputs an estimation result of whether or not power supply is possible via the input/output section 33, and causes the display device to display the estimation result.

The communication section 34 includes a communication interface that achieves communication with an external apparatus. The control section 31 transmits and receives various kinds of data including an estimation result of the power supply performance to and from an external apparatus through the communication section 34. The external apparatus communicably connected via the communication section 34 may be a host apparatus (for example, the vehicle ECU 71).

A method of estimating power supply performance according to the present example embodiment will be described. As the estimation of the power supply performance, the estimation apparatus 3 estimates a voltage behavior of the energy storage apparatus 1 when energization is performed in the assumed energization pattern, and estimates whether or not energization (power supply) in the assumed energization pattern is possible, based on the estimation result of the voltage behavior. In the estimation method according to the present example embodiment, when estimating the voltage behavior, an estimated value of the voltage behavior is corrected in consideration of an error in the estimated state value obtained by estimating the state of the energy storage apparatus 1, thereby improving the accuracy of determining whether or not energization in the assumed energization pattern is possible. Hereinafter, a method of estimating whether or not energization is possible will be explained, and then a method of estimating voltage behavior will be described in detail.

In the estimation of whether or not energization is possible, it is estimated whether energization in a specific assumed energization pattern is possible. In the estimation of whether or not the energization is possible, for example, it may be estimated whether the voltage of the energy storage apparatus 1 is lower than a voltage threshold value set in advance by the energization in the assumed energization pattern, or whether the current of the energy storage apparatus 1 exceeds a dischargeable current. The assumed energization pattern is, for example, a current pattern based on the amount of current consumption of various electric loads 72 mounted on a vehicle provided with the energy storage apparatus 1, and is a current pattern based on an energization time and an operating voltage range of the energy storage apparatus 1. The operating voltage range is, for example, a battery voltage threshold value or a voltage threshold value determined according to the electric load 72 mounted on the vehicle, and is given a lower limit voltage of the energy storage apparatus 1 during discharge, and an upper limit voltage of the energy storage apparatus 1 during charge. The operating voltage range may be a cell voltage threshold value set for each energy storage cell 2. The energization time, the operating voltage range, and the current value according to the assumed energization pattern may be given from, for example, a host apparatus, or may be stored in the storage section 32 in advance as an assumed energization pattern that has been set.

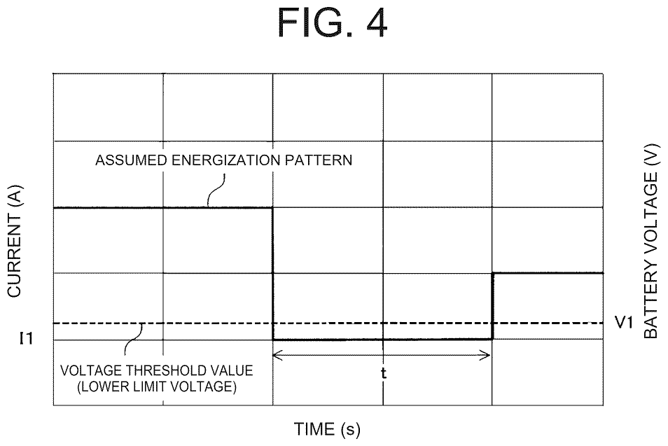

FIG. 4 is a diagram illustrating an example of the assumed energization pattern. In a graph illustrated in FIG. 4, a horizontal axis represents time (unit: seconds (s)), a left vertical axis represents current (unit: amperes (A)), and a right vertical axis represents battery voltage (unit: V). The value increases toward the right side of the horizontal axis, and the value increases toward the upper side of the vertical axis. The left vertical axis represents that the current value decreases, that is, discharge is performed with a large current, toward the downward direction.

In FIG. 4, as the assumed energization pattern, a case where discharge is performed in a current I1 for t seconds is illustrated. The battery voltage threshold value is a voltage value V1. The assumed energization pattern is not limited to that related to discharge, and may be that related to charge. A plurality of patterns may be set as the assumed energization pattern.

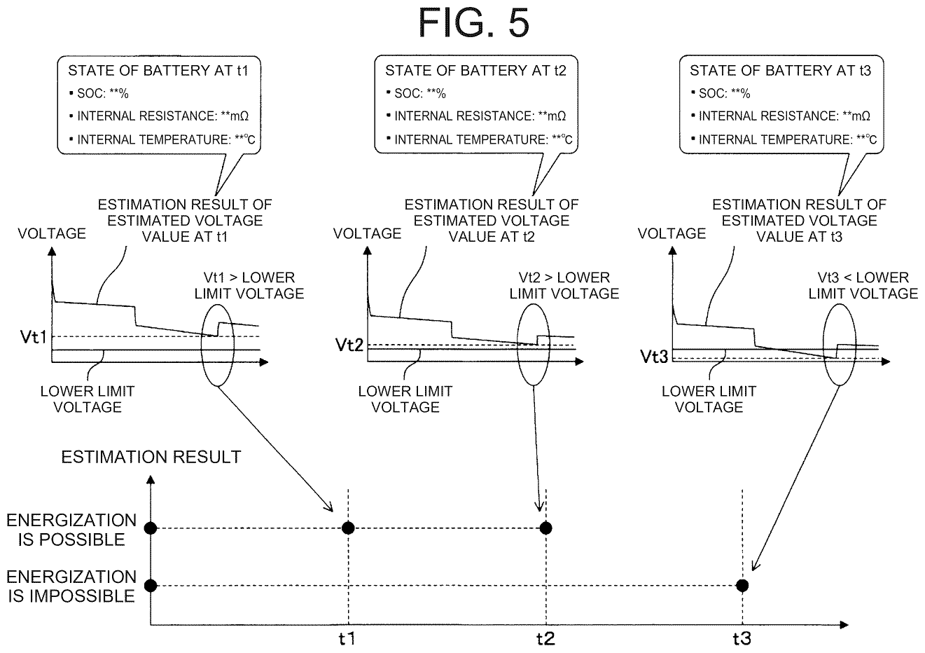

FIG. 5 is a diagram illustrating a method of estimating whether or not energization in an assumed energization pattern is possible. In FIG. 5, an upper graph illustrates a time change in the estimated voltage value of the energy storage apparatus 1 due to energization in the assumed energization pattern, and a lower graph illustrates an estimation result as to whether or not energization is possible. FIG. 5 illustrates an example of estimating whether or not energization is possible when energization is performed in the assumed energization pattern illustrated in FIG. 4, in a case where the energy storage apparatus 1 is used in a discharge state. The estimation apparatus 3 may execute the estimation process constantly (for example, every one second) when the energy storage apparatus 1 is used. FIG. 5 illustrates estimated voltage values of the energy storage apparatus 1 estimated at different estimation time points t1, t2, and t3, and an estimation result as to whether or not energization is possible.

When the energy storage apparatus 1 is discharged at a predetermined current value in the assumed energization pattern for a predetermined energization time, the estimated voltage value of the energy storage apparatus 1 decreases over time during discharge, as illustrated on the upper side of FIG. 5. The estimation apparatus 3 estimates, at each of the estimation time points t1, t2, and t3, whether the estimated voltage value after energization in the assumed energization pattern exceeds a predetermined operating voltage range (whether the estimated voltage value is lower than a lower limit voltage set in advance). When the estimated voltage value after energization does not exceed the operating voltage range (does not fall below the lower limit voltage), it can be estimated that energization is possible. When the estimated voltage value after energization exceeds the operating voltage range (falls below the lower limit voltage), it can be estimated that energization is impossible.

Although details will be described below, the estimation apparatus 3 obtains an estimated voltage value after energization in the assumed energization pattern by giving an estimated state value indicating a state of the energy storage apparatus 1 at an estimation time point to the energy storage device model. The estimated state value includes, for example, an SOC, an internal resistance, an internal temperature, and the like of the energy storage apparatus 1. The estimated state value of the energy storage apparatus 1 changes with the lapse of time. Whether or not energization is possible is estimated depending on the state of the energy storage apparatus 1 at each estimation time point.

As illustrated in FIG. 5, at the estimation time point t1 and the estimation time point t2, estimated voltage values Vt1 and Vt2 after energization in the assumed energization pattern are larger than the lower limit voltage, and therefore it is estimated that energization is possible. At the estimation time point t3, an estimated voltage value Vt3 after energization in the assumed energization pattern is smaller than the lower limit voltage, and therefore it is estimated that energization is impossible.

An estimation method of an estimated voltage value used for estimating whether or not energization is possible will be explained.

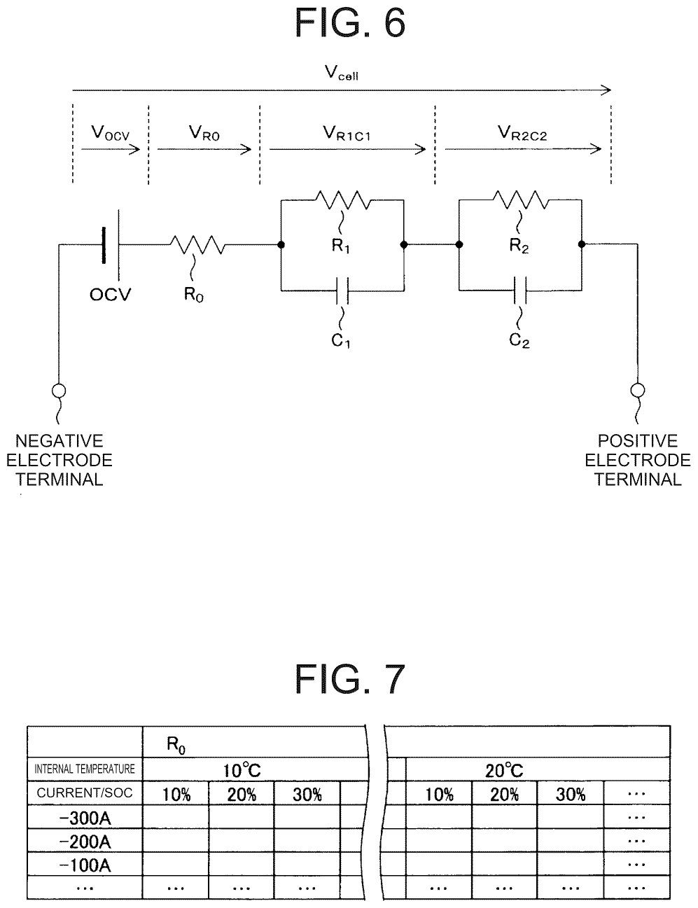

The estimation apparatus 3 obtains an estimated voltage value of the energy storage apparatus 1 by using the energy storage device model. FIG. 6 is a circuit diagram illustrating an example of the energy storage device model. The energy storage device model illustrated in FIG. 6 as an example is an equivalent circuit model, and simulates charge/discharge behavior of the energy storage cell 2 by combining a voltage source of the energy storage cell 2 and circuit elements such as a resistor and a capacitor.

In the example illustrated in FIG. 6, the equivalent circuit model includes a constant voltage source connected in series between the positive electrode terminal and the negative electrode terminal, a DC resistor for simulating a DC resistance component, and an RC parallel circuit for simulating a transient polarization characteristic. Although FIG. 6 illustrates an equivalent circuit model in which two RC parallel circuits, i.e., a first RC parallel circuit and a second RC parallel circuit, are connected in series, the number of stages of the RC parallel circuits is not limited to two.

The constant voltage source is a voltage source that outputs a DC voltage. The voltage being output by the constant voltage source is an open circuit voltage (OCV) of the energy storage cell 2, and is described as V_{OCV}. The open circuit voltage V_{OCV} is given as, for example, a function of the SOC. The open circuit voltage V_{OCV} may be given as a function of the actual capacity of the energy storage cell 2.

The DC resistor is for simulating a DC resistance component (DC impedance) of the energy storage cell 2, and includes a resistive element R₀. The resistive element R₀ is given as a value that varies depending on an energization current, a voltage, an SOC, an internal temperature, or the like. If the impedance of the DC resistor is determined, a voltage generated in the DC resistor when a current I flows through the equivalent circuit model can be calculated. The voltage generated in the DC resistor is referred to as a DC resistance voltage V_{R0}.

The first RC parallel circuit is constituted by a resistive element R₁ and a capacitive element C₁ connected in parallel. The second RC parallel circuit is constituted by a resistive element R₂ and a capacitive element C₂ connected in parallel. The resistive elements R₁ and R₂ and the capacitive elements C₁ and C₂ constituting each of the RC parallel circuits are given as values that vary depending on the energization current, the SOC, the internal temperature, and the like. The impedance of the RC parallel circuit is determined by the resistive elements R₁ and R₂ and the capacitive elements C₁ and C₂. If the impedance of the RC parallel circuit is determined, a voltage generated in the RC parallel circuit when the current I flows through the equivalent circuit model can be calculated. The voltage generated in the RC parallel circuit is a total voltage of a polarization voltage V_{R1C1} generated in the first RC parallel circuit and a polarization voltage V_{R2C2} generated in the second RC parallel circuit.

In the equivalent circuit model described above, a terminal voltage (estimated voltage value) V_{cell} of the energy storage cell 2, which is generated when energization is performed in the assumed energization pattern, is estimated. The estimated voltage value V_{cell} of the energy storage cell 2 at a time point of tₙ seconds later can be estimated by the following Equation (1) using the open circuit voltage V_{OCV}, the current I, the resistive elements R₀, R₁, and R₂, and the capacitive elements C₁ and C₂.

$$\begin{matrix}[ Math 1 ] & \\ & ( 1 )\end{matrix}$$

$${V}_{cell} = {V}_{ocv} ( {t}_{n} ) + {R}_{0} \text{?} + {R}_{1} \text{?} \times ( 1 - ex \text{?} ) + \text{?} ( {t}_{n - 1} ) \times ex \text{?} + {R}_{2} \text{?} \times ( 1 - ex \text{?} ) + \text{?} ( {t}_{n - 1} ) \times ex \text{?}$$

$$\text{?} \text{indicates text missing or illegible when filed}$$

In Equation (1), the open circuit voltage V_{OCV} may be obtained from the SOC at the estimation time point by using, for example, an SOC-OCV table. The SOC at the estimation time point may be calculated by a current integration method. The SOC-OCV table may be provided for each temperature, or a common table may be used. As the current I, a measured current value by the current sensor 66 can be used. The current I has, for example, a positive value in the case of charge, and a negative value in the case of discharge.

By calculating a total value of the estimated voltage values V_{cell} of the energy storage cells 2 obtained by Equation (1), a voltage (estimated voltage value) V_{bat} of the energy storage apparatus 1 is obtained. The estimated voltage value V_{bat} of the energy storage apparatus 1 may be a value obtained by subtracting a voltage drop due to a structural resistance in the energy storage apparatus 1 from the total value of the estimated voltage values V_{cell} of the energy storage cells 2. The structural resistance is, for example, a resistive component of the conductive member.

The resistive elements R₀, R₁, and R₂ and the capacitive elements C₁ and C₂ (hereinafter also referred to as circuit parameters) used in the equivalent circuit model are obtained in advance, based on actual measurement data or the like, according to the purpose of the energy storage apparatus 1 to be simulated. The circuit parameters are stored in advance in the storage section 32 of the estimation apparatus 3. The circuit parameters are stored, for example, in a data table format.

FIG. 7 is a conceptual diagram illustrating an example of a data table of circuit parameters. As illustrated in FIG. 7, in the data table of circuit parameters, the circuit parameters are stored in association with, for example, the internal temperature, the SOC, and the energization current of the energy storage apparatus 1. FIG. 7 illustrates a data table in which the resistive element R₀ is stored with respect to the internal temperature, the SOC, and the energization current for each predetermined interval. A data table is similarly prepared for each of the circuit parameters other than the resistive element R₀, and each circuit parameter is set in association with the internal temperature, the SOC, and the energization current.

The estimation apparatus 3 acquires the circuit parameter by, for example, communication with an external apparatus, and stores the acquired circuit parameter in the estimation data 322 of the storage section 32. The data table of the circuit parameters may be updated as appropriate according to an estimation result of the internal resistance value of the energy storage apparatus 1.

In estimating the estimated voltage value V_{cell}, the estimation apparatus 3 reads, from the data table, circuit parameters corresponding to the internal temperature, the SOC, and the energization current of the energy storage apparatus 1 at the estimation time point. By substituting the read circuit parameters and other input values into Equation (1), the estimated voltage value V_{cell} is obtained.

By calculating the total value of the estimated voltage values V_{cell} of the energy storage cells 2 obtained by Equation (1), a voltage (estimated voltage value) V_{bat} of the energy storage apparatus 1 is obtained.

The estimation results of the estimated voltage value V_{cell} and the estimated voltage value V_{bat} depend on the internal resistance, the internal temperature, and the SOC of the energy storage apparatus 1. The internal resistance, the internal temperature, and the SOC of the energy storage apparatus 1 are values indicating the state of the energy storage apparatus 1, and cannot be directly measured. Therefore, in order to estimate the estimated voltage value V_{bat}, it is necessary to use an estimated state value obtained by estimating the state of the energy storage apparatus 1.

The estimated state value can be estimated by various estimation functions. The estimation by the various estimation functions cannot necessarily completely reflect the state of each energy storage apparatus 1, and an estimation error is considered to occur. When the above-described circuit parameter is obtained based on the internal temperature and the SOC having an error, the value of the circuit parameter deviates, and as a result, an error occurs in the estimated voltage value V_{bat}. When the estimated voltage value V_{bat} is estimated by using an internal resistance having an error, an error occurs in the estimated voltage value V_{bat}.

Further, the output of the equivalent circuit model is also a type of estimated state value. The equivalent circuit model cannot necessarily completely consider the characteristics of the individual energy storage cells 2, and it is also considered that an error occurs between the estimated voltage value V_{bat}, which is output by using the equivalent circuit model, and a voltage value when the energy storage apparatus 1 is actually energized.

By considering the error in the estimated state value, the estimated voltage value V_{bat} can be estimated more appropriately. Since there are a plurality of types of errors in the estimated state value that can cause an error in the estimated voltage value V_{bat}, it is necessary to comprehensively consider individual voltage errors that occur due to the errors in each estimated state value. In the present example embodiment, attention is focused on the fact that errors of a plurality of estimated state values occur independently of each other (are not dependent on each other), and each individual voltage error that occurs due to errors of each estimated state value is obtained. The individual voltage error corresponds to an individual correction value (V) for the estimated voltage value V_{bat}. A final voltage error is obtained by summing up the obtained voltage errors. The final voltage error is a correction value (V) for the estimated voltage value V_{bat}, and is described as ΔVₑᵣᵣₒᵣ. By correcting the estimated voltage value V_{bat} by using the obtained correction value ΔVₑᵣᵣₒᵣ, a final estimated voltage value ΔV_{bat_error} is estimated.

Since the errors of the plurality of estimated state values are not dependent on each other, a possibility that the errors of the respective estimated state values simultaneously become the maximum error is extremely low. When the maximum error in each estimated state value is used, there is a concern that the correction value ΔVₑᵣᵣₒᵣ is excessively estimated, and it is estimated that energization is impossible earlier than originally. When the correction value ΔVₑᵣᵣₒᵣ is obtained by using only an error in a specific estimated state value, the correction value ΔVₑᵣᵣₒᵣ may be underestimated, and whether or not power supply is possible may be erroneously estimated. By obtaining the error in each estimated state value and determining the correction value ΔVₑᵣᵣₒᵣ, it is possible to appropriately estimate the charge acceptance performance or the discharge performance of the energy storage apparatus 1 without overestimating or underestimating the charge acceptance performance or the discharge performance.

An estimation error in the voltage due to an error in the SOC is defined as an SOC error, and is described as ΔV_{soc}. An estimation error in the voltage due to the error in the internal resistance is defined as an internal resistance error, and is described as ΔV_{Ri}. An estimation error in the voltage due to an error in the internal temperature is defined as a temperature error, and is described as ΔV_{Tcell}. An estimation error in the voltage due to an error that may occur between the estimated voltage value V_{bat} and the voltage value when the energy storage apparatus 1 is actually energized is defined as a model error, and is described as ΔV_{model}.

As an example, the correction value ΔVₑᵣᵣₒᵣ can be expressed by the following Equation (2) using the SOC error ΔV_{soc}, the internal resistance error ΔV_{Ri}, the temperature error ΔV_{Tcell}, and the model error ΔV_{model}.

$$\begin{matrix}[ Math 2 ] & \\ Δ {V}_{error} = \sqrt{{( Δ {V}_{soc} )}^{2} + {( Δ {V}_{Ri} )}^{2} + {( Δ {V}_{Tcell} )}^{2} + {( Δ {V}_{model} )}^{2}} & ( 2 )\end{matrix}$$

By correcting the estimated voltage value V_{bat} using the correction value ΔVₑᵣᵣₒᵣ, a final estimated voltage ΔV_{bat_error in} the energy storage apparatus 1, which takes into account errors of the estimated state values, is obtained. The estimated voltage ΔV_{bat_error} can be estimated by the following Equation (3) using the estimated voltage value V_{bat} and the voltage error ΔVₑᵣᵣₒᵣ.

$$Δ {V}_{bat \_ error} = {V}_{bat} - Δ {V}_{error} \qquad ( 3 )$$

As expressed by the above Equation (2), the correction value ΔVₑᵣᵣₒᵣ is the sum of individual voltage errors. In the present example embodiment, each individual voltage error is obtained based on each estimated state value.

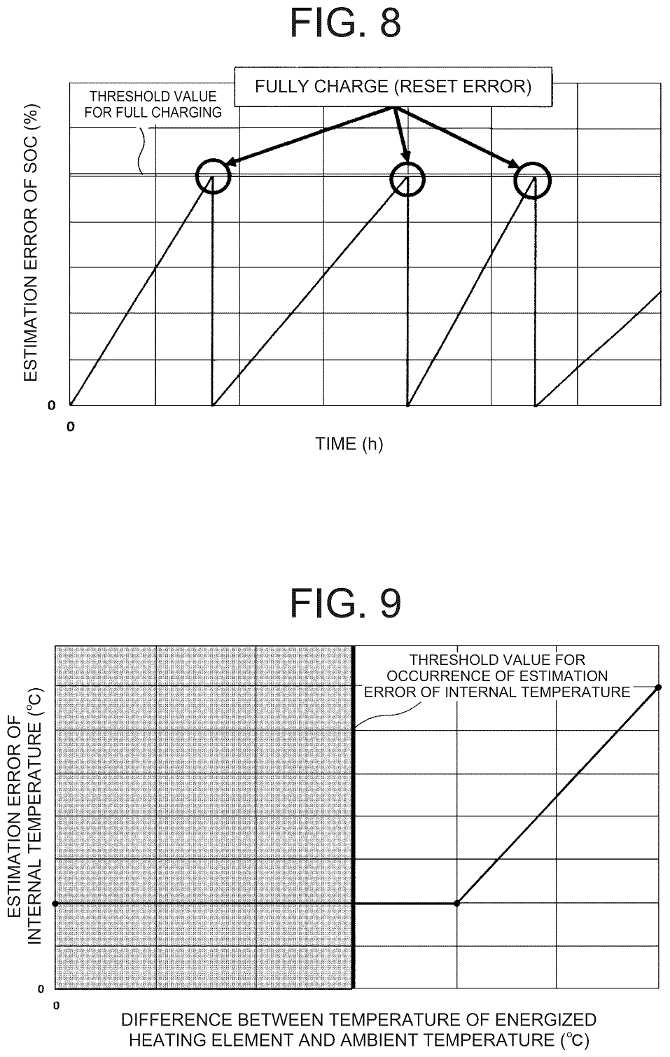

FIG. 8 is a diagram explaining a method of estimating an SOC error. The SOC error ΔV_{soc} can be estimated based on data on a relationship between a time from a full-charge time point and an estimation error in the SOC. The graph illustrated in FIG. 8 illustrates an example of the above-described relationship. In the graph illustrated in FIG. 8, a horizontal axis represents time (unit: h), and a vertical axis represents the estimation error in the SOC (unit: %). The value increases toward the right side of the horizontal axis, and the value increases toward the upper side of the vertical axis.

The SOC of the energy storage apparatus 1 can be estimated by a current integration method, as an example. By the current integration method, the SOC is obtained by integrating current values that are input to and output from the energy storage apparatus 1 after full charge, with the SOC value of the previous fully charged state as a reference. In the current integration method, an estimation error (%) of the SOC occurs due to a measurement error in the current sensor 66. Normally, when the estimation error in the SOC exceeds a preset threshold value for performing full charge, the estimation error in the SOC is reset by fully charging the energy storage apparatus 1. The estimation error in the SOC can be reset by estimating the SOC using, for example, an OCV method (i.e., by performing an OCV reset). The OCV method is a method of determining the SOC from the OCV of the energy storage apparatus 1, based on a correlative relationship between the SOC and the OCV.

As illustrated in FIG. 8, as the elapsed time from a predetermined timing (reference time point) increases, the estimation error (%) of the SOC tends to increase. The predetermined timing is a previous (most recent) full-charge time point, i.e., a timing at which the previous error has been reset. In order to reflect such a tendency, data on the relationship between the time from the full-charge time point and the estimation error in the SOC is generated. By holding the generated data on the relationship in advance, an estimation error in the SOC is obtained based on the data on the above-described relationship and the elapsed time from the previous full-charge time point.

Since the relationship between the time from the full-charge time point and the estimation error in the SOC changes depending on the internal temperature of the energy storage apparatus 1, a history of the internal temperature of the energy storage apparatus 1 may be taken into consideration when determining the estimation error in the SOC. For example, the lower the internal temperature of the energy storage apparatus 1, the greater a self-discharge amount of the energy storage apparatus 1, and therefore, the SOC may be estimated in such a way that the estimation error becomes larger.

The SOC error ΔV_{soc} is obtained by calculating a difference between the estimated voltage value V_{bat} when using an SOC value taking into account the estimation error in the SOC and the estimated voltage value V_{bat} when using an SOC value not taking into account the estimation error in the SOC. In the following description, the estimated voltage value V_{bat} when taking into account an estimation error in an estimated state value such as SOC is obtained by applying the estimated state value taking into account the obtained estimation error to the equivalent circuit model. The estimated state value taking into account the estimation error is, for example, an SOC obtained by adding or subtracting the estimation error in the SOC to or from an SOC calculated by the current integration method.

Similarly, the internal resistance error ΔV_{Ri} can be estimated based on data of a relationship between a time from a predetermined timing (reference time point) and an estimation error in the internal resistance. The predetermined timing (reference time point) is a time point of previous estimation of the internal resistance. More specifically, it is a time point of previous estimation of the internal resistance under a condition in which the internal resistance can be accurately estimated. An estimation error (mΩ) of the internal resistance of the energy storage apparatus 1 tends to increase as the elapsed time from the time point of previous estimation of the internal resistance increases. In order to reflect such a tendency, data on the relationship between the time from the estimation time point of the internal resistance and the estimation error in the internal resistance is generated. By holding the generated data on the above-described relationship in advance, the estimation error in the internal resistance is obtained based on the data of the above-described relationship and the elapsed time from the time point of previous estimation of the internal resistance. The estimation time point of the internal resistance under the condition in which the internal resistance can be accurately estimated may be, for example, a timing at which an amount of current suitable for estimating the internal resistance flows, such as during cranking in which a crankshaft of an engine is rotated to start the engine, or during high-voltage system activation.

Since the relationship between the time from the estimation time point of the internal resistance and the estimation error in the internal resistance changes depending on the internal temperature of the energy storage apparatus 1, the history of the internal temperature of the energy storage apparatus 1 may be taken into consideration when determining the estimation error in the internal resistance. For example, the lower the internal temperature of the energy storage apparatus 1, the greater a degree of degradation of the energy storage apparatus 1, and therefore, the internal resistance may be estimated in such a way that the estimation error becomes larger.

The internal resistance error ΔV_{Ri} is obtained by calculating a difference between the estimated voltage value V_{bat} when using an internal resistance value taking into account the estimation error in the internal resistance, and the estimated voltage value V_{bat} when using an internal resistance value not taking into account the estimation error in the internal resistance.

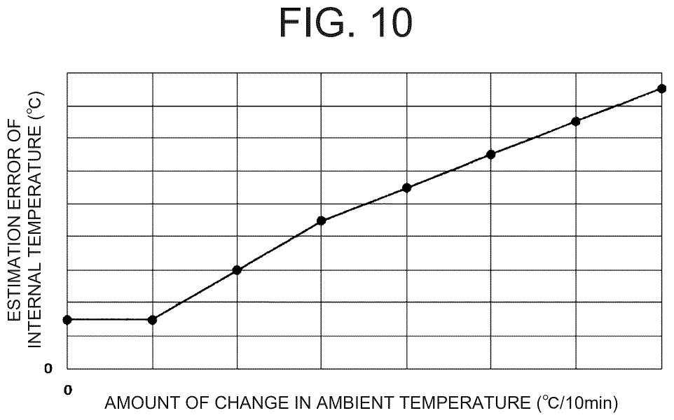

FIG. 9 is a diagram explaining a method of estimating a temperature error caused by energization of a current, and FIG. 10 is a diagram explaining a method of estimating a temperature error caused by a change in ambient temperature. The temperature error ΔV_{Tcell} includes a first temperature error ΔV_{Tcell} due to an energization amount (charge/discharge amount) associated with actual charge or discharge, and a second temperature error ΔV_{Tcell} due to a change in the ambient temperature of the energy storage apparatus 1.

A method of estimating the first temperature error ΔV_{Tcell} will be explained with reference to FIG. 9. The first temperature error ΔV_{Tcell} can be estimated based on data of a relationship between the energization amount of the energy storage apparatus 1 and the estimation error in the internal temperature. A graph illustrated in FIG. 9 illustrates an example of the above-described relationship. A horizontal axis of the graph illustrated in FIG. 9 represents a difference (unit: ° C.) between the temperature of the energized heating element and the ambient temperature, as data indicating the energization amount of the energy storage apparatus 1. A vertical axis represents an estimation error (unit: ° C.) of the internal temperature. The value increases toward the right side of the horizontal axis, and the value increases toward the upper side of the vertical axis.

In the present example embodiment, the energization amount of the energy storage apparatus 1 is grasped by using the temperature (measured temperature value) of the energized heating element measured by the second temperature sensor 65. As described above, the temperature of the energized heating element changes according to the energization amount of the energy storage apparatus 1. A larger difference between the temperature of the energized heating element and the ambient temperature measured by the first temperature sensor 64 indicates a larger energization amount. Alternatively, the energization amount of the energy storage apparatus 1 may be obtained based on, for example, the amount of electric power obtained from the current sensor 66 and the voltage sensor 67.

Since the internal temperature (cell temperature) of the energy storage apparatus 1 cannot be directly measured, the ambient temperature (measured temperature value) acquired by using the first temperature sensor 64 is used as the temperature related to the energy storage apparatus 1. When the energy storage apparatus 1 is energized, the internal temperature rapidly increases in response to heat generation in the energy storage apparatus 1, whereas it takes time for the measured temperature value of the first temperature sensor 64 to reach the same temperature as the internal temperature. A deviation between the internal temperature and the measured temperature value of the first temperature sensor 64 is an estimation error (° C.) of the internal temperature.

As illustrated in FIG. 9, the estimation error in the internal temperature tends to increase as the difference between the temperature of the energized heating element and the ambient temperature, i.e., the energization amount of the energy storage apparatus 1 increases. In order to reflect such a tendency, data on the relationship between the energization amount and the estimation error in the internal temperature is generated. The estimation error in the internal temperature is obtained based on the generated data on the above-described relationship and an energization amount at the estimation time point. As described above, by providing, in the energy storage apparatus 1, the first temperature sensor 64 for detecting the temperature of the normal energy storage apparatus 1 and the second temperature sensor 65 for correcting the temperature error, the estimation error in the internal temperature is accurately obtained.

When the energization amount is relatively small, it is considered that the estimation error in the internal temperature is minute, and therefore, as illustrated in FIG. 9, a threshold value for occurrence of the estimation error in the internal temperature may be set in advance. The estimation error in the internal temperature may be estimated only when the energization amount at the estimation time point is greater than or equal to the threshold value for occurrence of the estimation error.

The first temperature error ΔV_{Tcell} is obtained by calculating a difference between the estimated voltage value V_{bat} when using an internal temperature value taking into account the estimation error in the internal temperature and the estimated voltage value V_{bat} when using an internal temperature value not taking into account the estimation error in the internal temperature.

A method of estimating the second temperature error ΔV_{Tcell} will be explained with reference to FIG. 10. The second temperature error ΔV_{Tcell} can be estimated based on data on a relationship between an amount of change in the ambient temperature of the energy storage apparatus 1 and the estimation error in the internal temperature. A graph illustrated in FIG. 10 illustrates an example of the above-described relationship. A horizontal axis of the graph illustrated in FIG. 10 represents an amount of change (unit: ° C.) in the ambient temperature for each unit time (10 minutes in the example of FIG. 10), and a vertical axis represents an estimation error (unit: ° C.) of the internal temperature. The value increases toward the right side of the horizontal axis, and the value increases toward the upper side of the vertical axis.

When a change in the ambient temperature of the energy storage apparatus 1 is drastic, the measured temperature value by the first temperature sensor 64 changes to the vicinity of the ambient temperature relatively quickly, whereas it takes time until the inside of the energy storage apparatus 1 reaches the same temperature as the ambient temperature.

As illustrated in FIG. 10, the estimation error in the internal temperature tends to increase as an amount of change in the ambient temperature increases. In order to reflect such a tendency, data on the relationship between the amount of change in the ambient temperature and the estimation error in the internal temperature is generated. The estimation error in the internal temperature is obtained based on the generated data on the above-described relationship and an amount of change of the ambient temperature at the estimation time point.

The second temperature error ΔV_{Tcell} is obtained by calculating a difference between the estimated voltage value V_{bat} when using the internal temperature value taking into account the estimation error in the internal temperature and the estimated voltage value V_{bat} when using the internal temperature value not taking into account the estimation error in the internal temperature.

In the energy storage apparatus 1, since it is estimated that the first temperature error ΔV_{Tcell} and the second temperature error ΔV_{Tcell} are unlikely to occur at the same time, only one of the first temperature error ΔV_{Tcell} and the second temperature error ΔV_{Tcell} may be used in calculating the correction value ΔVₑᵣᵣₒᵣ. For example, when the energization amount at the estimation time point is greater than or equal to the threshold value for occurrence of the estimation error, the correction value ΔVₑᵣᵣₒᵣ may be obtained by using the first temperature error ΔV_{Tcell}, and when the energization amount at the estimation time point is less than the threshold value for occurrence of the estimation error, the correction value ΔVₑᵣᵣₒᵣ may be obtained by using the second temperature error ΔV_{Tcell}.

The model error ΔV_{model} can be estimated based on data on a relationship between the energy storage apparatus 1 and the model error ΔV_{model}. The data on the above-described relationship may be generated by obtaining a difference between a voltage value, which is a result of an energization test on a battery performed under the same conditions as those for the equivalent circuit model, and an estimated voltage value estimated by the equivalent circuit model.

When the energization time of the assumed energization pattern is relatively short, the estimation accuracy of the estimated voltage value by the equivalent circuit model is high, and the model error ΔV_{model} is negligibly small. When the energization time of the assumed energization pattern is relatively long, an increase in diffusion resistance of the energy storage cell 2 cannot be considered in the equivalent circuit model, and therefore, the estimation accuracy of the estimated voltage value by the equivalent circuit model is low, and the model error ΔV_{model} tends to be large. In order to reflect such a tendency, data on the relationship between the energy storage apparatus 1 and the model error ΔV_{model} is generated. Based on the generated data on the above-described relationship, the model error ΔV_{model} for the energy storage apparatus 1 is obtained. The data on the relationship between the energy storage apparatus 1 and the model error ΔV_{model} may be obtained in consideration of at least one of the magnitude of the current assumed energization pattern, the magnitude of the current fluctuation, or the number of times of the current fluctuation, instead of the energization time of the assumed energization pattern or in addition to the energization time of the assumed energization pattern.

Since the model error ΔV_{model} changes according to a length of the energization time of the assumed energization pattern, the data on the relationship between the energy storage apparatus 1 and the model error ΔV_{model} may be set in consideration of the energization time of the assumed energization pattern. The above-described relationship is set such that the model error ΔV_{model} increases as the energization time of the assumed energization pattern increases. Alternatively, the above-described relationship may be set such that the model error ΔV_{model} increases as the magnitude of the current of the assumed energization pattern increases. The above-described relationship may be set such that the model error ΔV_{model} increases as the magnitude of the current fluctuation in the assumed energization pattern increases. The above-described relationship may be set such that the model error ΔV_{model} increases as the number of times of energization in the assumed energization pattern increases.

Also when the energy storage cell 2 is polarized before the power supply performance is estimated, the model error ΔV_{model} tends to be large. The data on the relationship between the energy storage apparatus 1 and the model error ΔV_{model} may be set in consideration of a charge/discharge history before the estimation time point. When charge/discharge has been performed in the latest predetermined period before the estimation time point, the above-described relationship is set such that the model error ΔV_{model} increases. The above-described relationship may be set such that the model error ΔV_{model} increases as the charge/discharge current value increases, or the above-described relationship may be set such that the model error ΔV_{model} increases as the charge/discharge time increases.

The estimation apparatus 3 acquires data of the various relationships described above, and stores the acquired data on the various relationships in the estimation data 322 of the storage section 32 in advance. The data on various relationships may be stored as, for example, a graph, a table, a function formula, or the like indicating each relationship. All the data on various relationships can be generated by, for example, performing an energization test in advance. The data on the above-described relationship may be generated by an energization test using a test cell that is the same as that of the energy storage apparatus 1 whose power supply performance is to be estimated, or a test cell having a structure, a type, a composition, or the like similar to that of the energy storage apparatus 1.

As described with reference to FIG. 5, whether or not energization is possible is determined by comparing the estimated voltage ΔV_{bat_error} after being corrected by the correction value ΔVₑᵣᵣₒᵣ with the lower limit voltage or the upper limit voltage set in advance.

The example in which the estimated voltage value V_{cell} and the estimated voltage value V_{bat} are obtained based on the measurement data of the current, the voltage, and the temperature of the energy storage apparatus 1 acquired by various sensors and the equivalent circuit model has been explained above. Alternatively, the estimated voltage value V_{cell} and the estimated voltage value V_{bat} may be obtained based on an estimated value of the internal temperature, the SOC, the SOH and the like, and an equivalent circuit model.

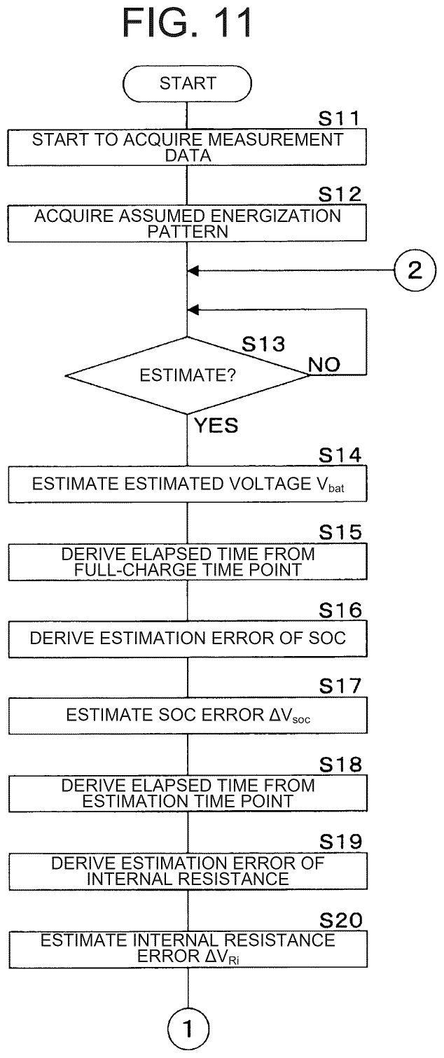

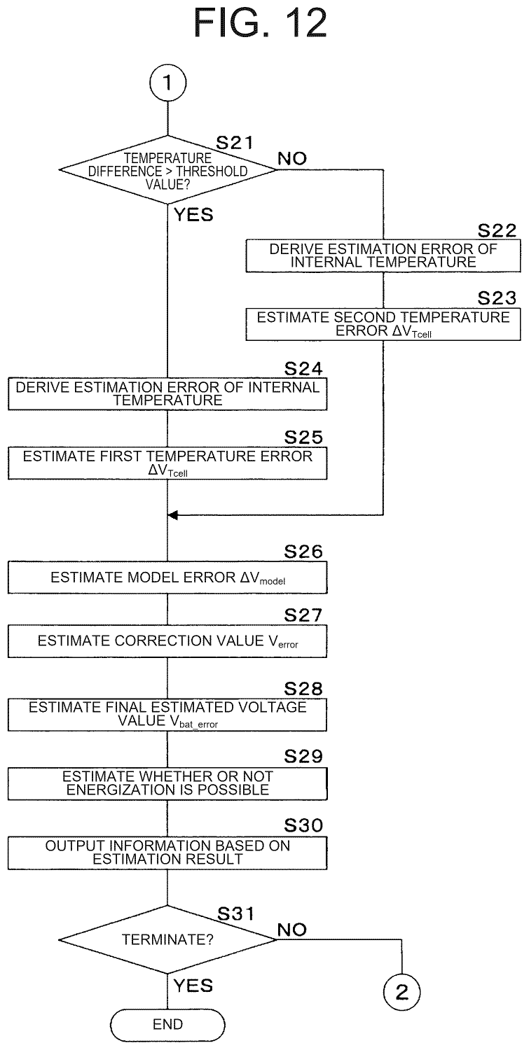

FIGS. 11 and 12 are flowcharts illustrating an example of a processing procedure to be executed by the estimation apparatus 3. The processing in the following flowchart may be executed by the control section 31 in accordance with the estimation program 321 stored in the storage section 32 of the estimation apparatus 3, may be achieved by a dedicated hardware circuit (for example, an FPGA or an ASIC) provided in the control section 31, or may be achieved by a combination thereof.

The control section 31 of the estimation apparatus 3 starts to acquire the measurement data of the current, the voltage, and the temperature of the energy storage apparatus 1 by the function as an acquisition section (step S11). The measurement data includes a measured current value by the current sensor 66, a measured voltage value by the voltage sensor 67, a measured temperature value of the ambient temperature by the first temperature sensor 64, and a measured temperature value of the temperature of the energized heating element by the second temperature sensor 65. Thereafter, the control section 31 acquires measurement data at a predetermined or appropriate interval, and stores the acquired measurement data in the storage section 32. Accordingly, time series measurement data is collected. The acquisition of the measurement data may be reading of the measurement data stored in the storage section 32.

The control section 31 may obtain the SOC of the energy storage apparatus 1 by, for example, a current integration method in response to the acquisition of the measurement data. The control section 31 may obtain the open circuit voltage V_{OCV} depending on the SOC at a measurement time point, based on the obtained SOC and the SOC-OCV table stored in the estimation data 322.

The control section 31 acquires an assumed energization pattern to be a target of the estimation process of the power supply performance (step S12). The control section 31 may acquire the assumed energization pattern by receiving, for example, an energization current value, an energization time, and an upper limit voltage or a lower limit voltage transmitted from a host apparatus.

The control section 31 determines whether to estimate the power supply performance (step S13). For example, when it is determined that the power supply performance is not to be estimated because it is not an estimation timing set in advance (step S13: NO), the control section 31 returns the process to step S13, and waits until the estimation timing is reached.

When it is determined that the power supply performance is to be estimated because it is the estimation timing set in advance (step S13: YES), the control section 31 estimates, by the function as an estimation section, the estimated voltage value V_{bat} of the energy storage apparatus 1 when energization is performed in the assumed energization pattern (step S14). The control section 31 estimates the estimated voltage value V_{cell} of each energy storage cell 2 by the equivalent circuit model, by using a measured current value, a measured voltage value, and a measured temperature value of the ambient temperature at the estimation time point. The control section 31 obtains the estimated voltage value V_{bat} of the energy storage apparatus 1 by calculating a total value of the estimated voltage values V_{cell} of the energy storage cells 2, which have been estimated. Each circuit parameter used for the equivalent circuit model is obtained based on the measured current value, the measured temperature value of the ambient temperature, and the SOC value by current integration at the estimation time point. The estimated voltage value V_{bat} is a voltage value not taking into account errors of various estimated state values.

The control section 31 derives an elapsed time from the previous full-charge time point, based on the charge/discharge history of the energy storage apparatus 1 (step S15). The control section 31 derives an estimation error in the SOC corresponding to the derived elapsed time, based on data of the relationship between the time from the full-charge time point and the estimation error in the SOC, which is stored in the storage section 32 (step S16).

The control section 31 estimates an SOC error ΔV_{soc} by calculating a difference between the estimated voltage value V_{bat} when taking into account the estimation error in the estimated SOC and the estimated voltage value V_{bat} when not taking into account the estimation error in the SOC estimated in step S14 (step S17).

The control section 31 derives an elapsed time from the previous estimation time point of the internal resistance, based on the charge/discharge history of the energy storage apparatus 1 (step S18). The control section 31 derives an estimation error in the internal resistance corresponding to the derived elapsed time, based on data on the relationship between the time from the estimation time point of the internal resistance and the estimation error in the internal resistance, which is stored in the storage section 32 (step S19).

The control section 31 estimates an internal resistance error ΔV_{Ri} by calculating a difference between the estimated voltage value V_{bat} when taking into account the estimation error in the estimated internal resistance and the estimated voltage value V_{bat} when not taking into account the estimation error in the internal resistance estimated in step S14 (step S20).

The control section 31 determines whether the difference in temperature between the ambient temperature and the temperature of the energized heating element is greater than or equal to a preset threshold value for occurrence of the estimation error in the internal temperature (step S21). The temperature difference between the ambient temperature and the temperature of the energized heating element is obtained by calculating a difference (an absolute value of the difference) between the measured temperature value of the ambient temperature by the first temperature sensor 64 and the measured temperature value of the temperature of the energized heating element by the second temperature sensor 65.

When it is determined that the temperature difference is less than the threshold value for occurrence of the estimation error (step S21: NO), the control section 31 derives the estimation error in the internal temperature, based on data on a relationship between the amount of change in the ambient temperature and the estimation error in the internal temperature, which is stored in the storage section 32 (step S22). The control section 31 calculates an amount of change in the ambient temperature in the latest unit time, based on the time-series measurement data stored in the storage section 32, and obtains an estimation error in the internal temperature corresponding to the calculated amount of change in the ambient temperature from the data on the above-described relationship.

The control section 31 estimates a second temperature error ΔV_{Tcell} as the temperature error ΔV_{Tcell} by calculating a difference between the estimated voltage value V_{bat} when taking into account the estimation error in the estimated internal temperature and the estimated voltage value V_{bat} when not taking into account the estimation error in the internal temperature estimated in step S14 (step S23).

When it is determined that the temperature difference is greater than or equal to the threshold value for occurrence of the estimation error (step S21: YES), the control section 31 derives an estimation error in the internal temperature, based on data on the relationship between the energization amount (the difference between the temperature of the energized heating element and the ambient temperature) and the estimation error in the internal temperature, which is stored in the storage section 32 (step S24). The control section 31 obtains an estimation error in the internal temperature corresponding to the calculated temperature difference from the data on the above-described relationship.

The control section 31 estimates a first temperature error ΔV_{Tcell} as the temperature error ΔV_{Tcell} by calculating a difference between the estimated voltage value V_{bat} when taking into account the estimation error in the estimated internal temperature and the estimated voltage value V_{bat} when not taking into account the estimation error in the internal temperature estimated in step S14 (step S25).

The control section 31 estimates the model error ΔV_{model}, based on data on the relationship between the energy storage apparatus 1 and the model error ΔV_{model}, which is stored in the storage section 32 (step S26).

In step S26, the control section 31 may specify the relationship data to be used, based on the length of the energization time of the assumed energization pattern, and estimate the model error ΔV_{model} by using the specified relationship data. The control section 31 may correct the estimated model error ΔV_{model} by using a correction factor depending on the length of the energization time of the assumed energization pattern in such a way that the model error ΔV_{model} increases according to the length of the energization time.

In step S26, the control section 31 may specify the relationship data to be used, based on the most recent charge/discharge history before the estimation time point, and estimate the model error ΔV_{model} by using the specified relationship data. The control section 31 may correct the estimated model error ΔV_{model} by using a correction factor depending on the most recent charge/discharge history in such a way that the model error ΔV_{model} increases according to charge/discharge.

The control section 31 estimates the correction value ΔVₑᵣᵣₒᵣ, based on the estimated SOC error ΔV_{soc}, the internal resistance error ΔV_{Ri}, the temperature error ΔV_{Tcell}, and the model error ΔV_{model} (step S27). As an example, the correction value ΔVₑᵣᵣₒᵣ can be set to a value of a root of a sum of squares of each of the SOC error ΔV_{soc}, the internal resistance error ΔV_{Ri}, the temperature error ΔV_{Tcell}, and the model error ΔV_{model}.

By the function as a correction section, the control section 31 corrects the estimated voltage value V_{bat} estimated in step S14 by using the estimated correction value ΔVₑᵣᵣₒᵣ, and estimates the final estimated voltage value ΔV_{bat_error} in the energy storage apparatus 1 (step S28).

The control section 31 estimates whether or not the energy storage apparatus 1 can be energized in the assumed energization pattern, based on the estimated voltage value ΔV_{bat_error} that has been estimated (step S29). The control section 31 estimates whether or not the energization is possible by determining whether the estimated voltage value ΔV_{bat_error} exceeds an operating voltage range of the assumed energization pattern.

The control section 31 outputs information based on the estimation result to a host apparatus, for example, via the communication section 34 (step S30), and ends a series of processes. The control section 31 may output, as the information based on the estimation result, the estimated voltage value ΔV_{bat_error} and whether or not the energization is possible, or may output at least one of them.

The control section 31 determines whether to end the estimation process (step S31). For example, when it is determined that the estimation process is not to be ended because a predetermined ending operation has not been executed (step S31: NO), the control section 31 returns the process to step S13, and repeats the estimation process. When it is determined that the estimation process is to be ended because the predetermined ending operation has been executed (step S31: YES), the control section 31 ends the series of processes.

In the above-described process, the estimation order of the SOC error ΔV_{soc}, the internal resistance error ΔV_{Ri}, the temperature error ΔV_{Tcell}, and the model error ΔV_{model} is not limited, and the estimation process of each error may be executed by changing the order, or may be processed in parallel.

According to the present example embodiment, it is possible to accurately estimate the power supply performance of the energy storage apparatus 1 by correcting the estimated voltage value of the energy storage apparatus 1, based on the error in the estimated state value of the energy storage apparatus 1.

The estimation apparatus, the estimation method, and the estimation program can be applied to applications other than vehicles, and may be applied to a flying object such as an aircraft, a flying vehicle, or a high altitude platform station (HAPS), or may be applied to a ship or a submarine. The estimation apparatus, the estimation method, and the estimation program are preferably applied to a mobile object for which a high level of safety is required (for which real-time calculation is required), but are not limited to the mobile object, and may be applied to a stationary energy storage apparatus.

The example embodiments disclosed herein are illustrative in all respects and are not restrictive. The technical features described in the example embodiments can be combined with each other, and the scope of the present invention is intended to include all modifications within the scope of the claims and a scope equivalent to the scope of the claims.

The sequence illustrated in each example embodiment is not limited, and each processing procedure may be executed by changing the order thereof as long as there is no internal contradiction, or a plurality of processes may be executed in parallel. A processing subject of each process is not limited, and the process of each device may be executed by an other device as long as there is no internal contradiction.

The matters described in the example embodiments can be combined with each other. Furthermore, the independent claims and the dependent claims recited in the claims can be combined with each other in any combination, regardless of the citation form. Furthermore, a form (multi-claim form) in which a claim citing two or more other claims is recited is used in the scope of the claims, but the present invention is not limited thereto. The present invention may be described by using a format of reciting a multi-claim (multi-multi-claim) in which at least one multi-claim is cited.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An estimation method comprising:
using an energy storage device model simulating a behavior of an energy storage device to estimate an estimated voltage value of the energy storage device when energization is performed in an assumed energization pattern; and
correcting the estimated voltage value that has been estimated by a correction value obtained based on an error in an estimated state value of the energy storage device.

2. The estimation method according to claim 1, further comprising:
acquiring a measured current value, a measured voltage value, and a measured temperature value of the energy storage device; wherein
the estimated voltage value is estimated by using the acquired measured current value, measured voltage value, and measured temperature value, and the energy storage device model.

3. The estimation method according to claim 1, wherein the correction value obtained is smaller than a sum of individual correction values obtained from maximum errors in a plurality of estimated state values of the energy storage device.

4. The estimation method according to claim 1, wherein the error in the estimated state value increases as an elapsed time from a predetermined timing increases.

5. The estimation method according to claim 4, wherein
the estimated state value and the error in the estimated state value are obtained based on previously held data relating to a relationship between a time from a full-charge time point and an estimation error in the estimated state value, and an elapsed time from a previous full-charge time point.

6. The estimation method according to claim 4, wherein
the estimated state value includes an internal resistance;
and
an error in the internal resistance is obtained based on previously held data relating to a relationship between a time from an estimation time point of the internal resistance and an estimation error in the internal resistance, and an elapsed time from a time point of a previous estimation of the internal resistance.

7. The estimation method according to claim 1, wherein, among a plurality of estimated state values of the energy storage device, an error in an internal temperature of the energy storage device is increased depending on a magnitude of a change in an ambient temperature or a magnitude of an energization amount of the energy storage device.

8. The estimation method according to claim 1, wherein, among a plurality of estimated state values of the energy storage device, an error in an output of the energy storage device model is increased depending on at least one of a length of an energization time of the assumed energization pattern, a magnitude of current, a magnitude of current fluctuation, or a number of times of current fluctuation.

9. The estimation method according to claim 1, wherein
the energy storage device is an energy storage assembly including a plurality of energy storage cells;
a measured voltage value and a measured temperature value of each of the plurality of energy storage cells are acquired; and
an estimated voltage value of the energy storage assembly is obtained from an estimated voltage value of each of the plurality of energy storage cells, the estimated voltage value being estimated by using the measured voltage value and the measured temperature value of each of the plurality of energy storage cells.

10. The estimation method according to claim 1, further comprising determining, based on the estimated voltage value and the correction value, whether or not the energy storage device can be charged or discharged in the assumed energization pattern.

11. A non-transitory computer-readable medium including an estimation program executable to cause a computer to perform:
using an energy storage device model simulating a behavior of an energy storage device to estimate an estimated voltage value of the energy storage device when energization is performed in an assumed energization pattern; and
correcting the estimated voltage value that has been estimated by a correction value obtained based on an error in an estimated state value of the energy storage device.

12. An estimation apparatus, comprising:
a processor;
a memory including a program executable by the processor to function as:
an estimation section configured or programmed to use an energy storage device model simulating a behavior of an energy storage device to estimate an estimated voltage value of the energy storage device when energization is performed in an assumed energization pattern; and
a correction section configured or programmed to correct the estimated voltage value that has been estimated by a correction value obtained based on an error in an estimated state value of the energy storage device.

13. An energy storage apparatus comprising the estimation apparatus according to claim 12.
